(19) United States
(12) Patent Application Publication
(10) Pub. No.: US 2026/0171840 A1
(43) Pub. Date: Jun. 18, 2026

(54) METHOD FOR ANALYZING MULTI-TEMPORAL GRID OPERATION TRACE BASED ON DIGITAL TWINS

(71) Applicant: State Grid Henan Electric Power Company Electric Power Science Research Institute, Zhengzhou (CN)

(72) Inventors: Ling Miao, Zhengzhou (CN); Jianwei Ma, Zhengzhou (CN); Yurong Hu, Zhengzhou (CN); Hao Liu, Zhengzhou (CN); Jian Zhao, Zhengzhou (CN); Rongze Niu, Zhengzhou (CN); Xiaozhao Wei, Zhengzhou (CN); Xiang He, Zhengzhou (CN)

(21) Appl. No.: 19/419,170

(22) Filed: Dec. 15, 2025

(30) Foreign Application Priority Data
Dec. 17, 2024 (CN) 202411857515.3

(51) Int. Cl. H02J 13/12; G01R 31/58; G06F 30/27; H02J 103/30

(52) U.S. Cl. CPC H02J 13/12; G01R 31/58; G06F 30/27; H02J 2103/30

(57) ABSTRACT

The present invention discloses a method for analyzing multi-temporal grid operation trace based on digital twins, including: S1 performing feature reduction on a set of original power grid sample data; S2 based on the set of original power grid sample data with performed feature reduction, building a power grid digital twin model; S3 based on the set of original power grid sample data with performed feature reduction, building a model for simulating multi-temporal power grid operation trace; and S4 generating trace data based on the power grid digital twin model, and inputting a hybrid dataset composed of the trace data and real-time data into the model for simulating multi-temporal power grid operation trace for analysis and assessment. By way of comprehensively analyzing multi-temporality, the present invention makes it possible to fully understand operation states of power grids and provide a scientific basis for scheduling power grids and decision-making.

### CROSS REFERENCE TO RELATED APPLICATIONS

The present application claims the benefit of Chinese Patent Application No. 202411857515.3 filed on Dec. 17, 2024, the contents of which are incorporated herein by reference in their entirety.

### FIELD OF THE INVENTION

The present invention relates to the technical field of power grid analysis, in particular to a method for analyzing multi-temporal grid operation trace based on digital twins.

### BACKGROUND OF THE INVENTION

An energy system is a large-scale, hierarchically complex and capital- and technology-intensive composite system currently in the world, characterized by nonlinearity, high dimensionality, stratification, distribution and the like. These complexities are particularly prominent in access to new energy sources and management of flexible loads in a system. With the advancement of the “carbon peaking and carbon neutrality” goal, the proportion of new energy in the energy system continues to increase. The uncertainties of wind and photovoltaic power generation are notable. For example, scenarios such as “extremely hot with no wind” or “no sunlight at a late peak” make an increase in difficulty of system balancing and pose a serious challenge to stability of power supply. With widespread access to renewable energy and increasing uncertainty of power grid environments, traditional grid monitoring and decision-making technologies have certain limitations in response to real-time complex grid control requirements. Especially in scenarios with multi-temporality and high randomness, how to fully leverage the flexibility of distributed resources (sources, networks, loads, storage) to improve stability and cost-effectiveness of systems has become an urgent problem that needs to be solved. Current lack of systems for high-efficiently simulating and analyzing multi-temporal grid operation trace, makes it difficult to achieve simulating cross-temporal grid operation data, assessing risks, and supporting intelligent decision. The digital twin technology can reflect operation states of physical power grids in real time by establishing a virtual-real mapped power grid model, so as to provide technical support for grid control and optimization.

Although many policy measures have been introduced to support the digital twin technology, it is still necessary at this stage to accelerate building intelligent scheduling systems and digital twin platforms, so as to aid the power grid in achieving stable operation and optimized scheduling in more complex scenarios. Therefore, the present invention has important theoretical and practical significance.

### SUMMARY OF THE INVENTION

In view of shortcomings in the prior art mentioned above, the present invention provides a method for analyzing multi-temporal grid operation trace based on digital twins.

In order to solve the above technical problem, as the technical solution adopted by the present invention, a method for analyzing multi-temporal grid operation trace based on digital twins including the following steps.
S1 Performing feature reduction on a set of original power grid sample data.
S2 Based on the set of original power grid sample data with performed feature reduction, building a power grid digital twin model.
S3 Based on the set of original power grid sample data with performed feature reduction, building a model for simulating multi-temporal power grid operation trace.
S4 Generating trace data based on the power grid digital twin model, and inputting a hybrid dataset composed of the trace data and real-time data into the model for simulating multi-temporal power grid operation trace for analysis and assessment.

Furthermore, in S1, the set of original power grid sample data involves load demand, power generation, line losses and transformer temperature characteristics.

Furthermore, in S1, performing feature reduction on a set of original power grid sample data by means of a Relief algorithm.

Furthermore, in S2, building a power grid digital twin model by means of a generative adversarial network, wherein the power grid digital twin model is configured to simulate operation states of power grids and map characteristics of power grids under different scenarios, so as to provide emulation support for subsequently simulating multi-temporal power grid operation trace.

Furthermore, in S3, building a model for simulating multi-temporal power grid operation trace by means of a Stacking algorithm.

Furthermore, the step of performing feature reduction on a set of original power grid sample data by means of a Relief algorithm is executed by the following sub-steps.
S11 Initialization and random instance selection:
selecting a set of original power grid sample data with performed feature reduction (D={(x₁,y₁), (x₂,y₂), . . . , (xₙ,yₙ)}, where xᵢ represents a feature vector and yᵢ represents a corresponding class label, then initializing a weight W[j] of each feature as zero, where (j=1, 2, . . . , m) and randomly selecting an instance x from the set of original power grid sample data with performed feature reduction as a current instance.
S12 Location of nearest neighbors and calculation of similarity:
computing a nearest neighbor of the current instance x, and calculating similarity in distance metric, wherein for a feature j, calculation of similarity can be defined as:

$$similarity ( {x}_{i} , {x}_{j} ) = exp ( - \frac{{d ( {x}_{i} , {x}_{j} )}^{2}}{{σ}^{2}} )$$

where, (d(xᵢ,xⱼ)) represents a distance between an instance xᵢ and an instance x_{J}, σ represents an adjustment parameter that controls a range of similarity.
S13 Update on feature weights
updating a feature weight for each feature j based on located similar and dissimilar neighbors; in other words, increasing a similarity score of a similar neighbor with respect to a current instance feature value, and decreasing a similarity score of a dissimilar neighbor;

$$W [ j ] ← W [ j ] + similarity ( x , {x}_{hit} ) - similarity ( x , {x}_{miss} )$$

where, the similar neighbor (xₕᵢₜ) is the most similar instance among identical classes; the dissimilar neighbor (xₘᵢₛₛ) is the most similar instance among different classes.

Repeating a course from S11-S13 many times until reaching a preset number of iterations or a convergence.

Furthermore, the generative adversarial network consists of a generator and a discriminator, wherein the generator performs a function of producing data real to the fullest extent from random noise, accepting a random noise vector z as input and outputting generated data G(z); and the discriminator performs a function of judging whether input data is real data x or fake data z generated by a generator. The discriminator outputs D(x) or D(G(z)), indicating a probability of the input data being real.

A process of training a power grid digital twin model is executed by minimizing an adversarial loss between the generator and the discriminator, and such a process is expressed by the following optimization objective function:

$${min}_{G} {max}_{D} V ( D , G ) = {E}_{x \sim {P}_{data} ( x )} [ log D ( x ) ] + {E}_{z \sim {P}_{z} ( z )} [ log ( 1 - D ( G ( z ) ) ) ]$$

where, P_{data}(x) represents a real data distribution, P_{z}(z) represents a noise distribution input by a generator, E represents an expected value.

The generator captures a distribution of real datasets and generates data real to the fullest extent; the discriminator judges whether the data is real or not; in this way, continuous iterative adversarial training simultaneously improves performance of the generator and the discriminator, and reaches its goal, that is, a balanced state in which the generator can produce data that is real enough that the discriminator cannot distinguish between real data and generated data.

Furthermore, the step of building a model for simulating multi-temporal power grid operation trace by means of a Stacking algorithm is executed by the following sub-steps.
S31 Selecting various machine learning algorithms as a foundation model.
S32 Training all foundation models by using a set of original power grid sample data with performed feature reduction, and enabling each foundation model to learn independently and generate a prediction; and using each foundation model to predict an original training set, so as to obtain a prediction result of each foundation model.
S33 Using a prediction result of each foundation model as a meta-feature, and selecting one foundation model as a meta-model, then training each meta-model with a corresponding meta-feature, so as to obtain a final prediction result.

Compared with the prior art, the present invention has the following beneficial effects.
1) Improving modeling accuracy and real-time performance: the present invention employs a model data fusion method to overcome difficulties in insufficient accuracy and low real-time performance during building a traditional device-level digital twin, thereby achieving precise dynamic modeling and real-time interaction for distributed energy devices. This method can more accurately reflect operation states status of equipment and improve capabilities of scheduling and optimizing power grids.
2) Multi-temporal dynamic simulation and analysis: this method is based on multi-scenario dynamic simulation “history-parallel-future”, and capable of covering real-time fluctuations and long-term trend changes of power grids, and supporting simulation of power grid operation data, risk assessment, and intelligent decision-making under different scenarios, making it possible for power grids to be more adaptable and flexible for complex environments.
3) Comprehensive risk assessment and optimized decision support: bay way of building a complete digital twin model and combining historical operation data with real-time data, it is possible to provide accurate risk assessment and sensitivity analysis. This system provides high-efficient data support for decision on scheduling and optimizing power grids, and contributes to an intelligent, high-efficient, and low-carbon modern power system.

### BRIEF DESCRIPTION OF THE DRAWINGS

FIG. 1 is a flowchart of the method of the present invention.

FIG. 2 is a flowchart of the generative adversarial network according to an embodiment of the invention.

FIG. 3 is a flowchart of executing an Stacking algorithm in an embodiment of the present invention.

### DETAILED DESCRIPTION OF SOME EMBODIMENTS

In order to make an objective, technical solution, and advantage of an embodiment of the present invention clearer, we shall clearly and completely describe the technical solution of the embodiment of the present invention with reference to the figures of the embodiment of the present invention as follows. Obviously, a described example is part of embodiments of the present invention, not all of them. Based on the described example of the present invention, all other embodiments obtained by a person skilled in the art fall within the protection scope of the present invention.

### Example

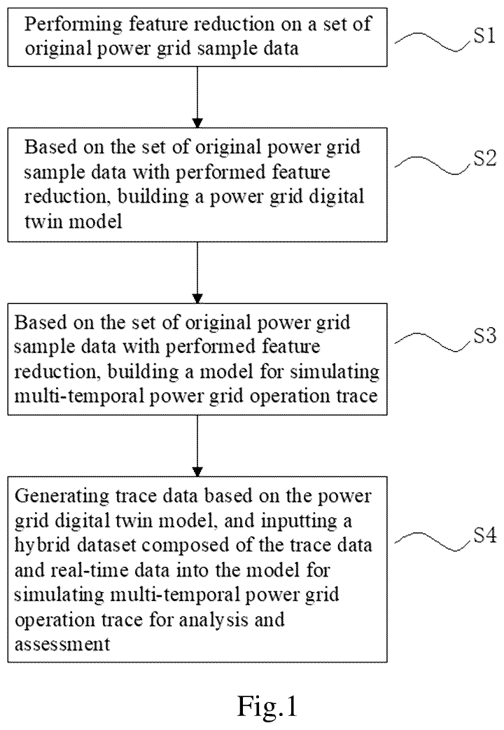

As shown in FIG. 1, a method for analyzing multi-temporal grid operation trace based on digital twins including the following steps.
S1 Performing feature reduction on a set of original power grid sample data.
S2 Based on the set of original power grid sample data with performed feature reduction, building a power grid digital twin model.
S3 Based on the set of original power grid sample data with performed feature reduction, building a model for simulating multi-temporal power grid operation trace.
S4 Generating trace data based on the power grid digital twin model, and inputting a hybrid dataset composed of the trace data and real-time data into the model for simulating multi-temporal power grid operation trace for analysis and assessment.

Specifically, in S1, the set of original power grid sample data involves load demand, power generation, line losses and transformer temperature characteristics, so as to better represent dynamic characteristics of power grids.

Specifically, in S1, performing feature reduction on a set of original power grid sample data by means of a Relief algorithm. By such a way, it is possible to reduce dimensionality of data, extract key features, and ensure efficiency and accuracy of simulation data. The step of performing feature reduction on a set of original power grid sample data by means of a Relief algorithm is executed by the following sub-steps.
S11 Initialization and random instance selection:
selecting a set of original power grid sample data with performed feature reduction (D={(x₁,y₁), (x₂,y₂), . . . , (xₙ,yₙ)}, where xᵢ represents a feature vector and yᵢ represents a corresponding class label, then initializing a weight W[j] of each feature as zero, where (j=1, 2, . . . , m) and randomly selecting an instance x from the set of original power grid sample data with performed feature reduction as a current instance.
S12 Location of nearest neighbors and calculation of similarity:
computing a nearest neighbor of the current instance x, and calculating similarity in distance metric, wherein for a feature j, calculation of similarity can be defined as:

$$similarity ( {x}_{i} , {x}_{j} ) = exp ( - \frac{{d ( {x}_{i} , {x}_{j} )}^{2}}{{σ}^{2}} )$$

where, (d(xᵢ,xⱼ)) represents a distance between an instance xᵢ and an instance xⱼ, σ represents an adjustment parameter that controls a range of similarity.
S13 Update on feature weights
updating a feature weight for each feature J based on located similar and dissimilar neighbors; in other words, increasing a similarity score of a similar neighbor with respect to a current instance feature value, and decreasing a similarity score of a dissimilar neighbor;

$$W [ j ] ← W [ j ] + similarity ( x , {x}_{hit} ) - similarity ( x , {x}_{miss} )$$

where, the similar neighbor (xₕᵢₜ) is the most similar instance among identical classes; the dissimilar neighbor (xₘᵢₛₛ) is the most similar instance among different classes.

Repeating a course from S11-S13 many times until reaching a preset number of iterations or a convergence.

Specifically, in S2, building a power grid digital twin model by means of a generative adversarial network (GAN), which is configured to accurately simulate operation states of power grids and map characteristics of power grids under different scenarios, so as to provide emulation support for subsequently simulating multi-temporal power grid operation trace. This model is based on simplified power grid characteristics and combines physical models with data-driven methods to achieve accurate emulation on power grids. By employing machine learning or deep learning techniques, it is possible to build a dynamic behavior model of power grids, and enable it to reflect operation states of power grids in real time.

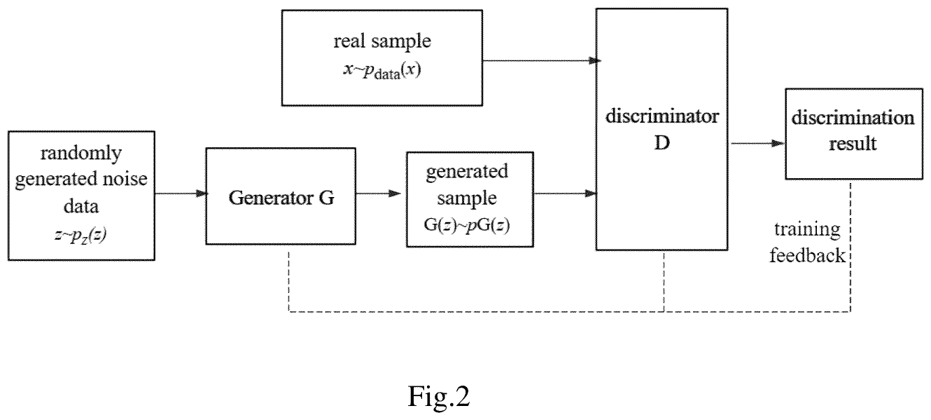

As shown in FIG. 2, the generative adversarial network (GAN) consists of a generator and a discriminator, wherein the generator performs a function of producing data real to the fullest extent from random noise, accepting a random noise vector z as input and outputting generated data G(z); and the discriminator performs a function of judging whether input data is real data x or fake data z generated by a generator. The discriminator outputs D(x) or D(G(z)) indicating a probability of the input data being real.

A process of training a power grid digital twin model is executed by minimizing an adversarial loss between the generator and the discriminator, and such a process is expressed by the following optimization objective function:

$${min}_{G} {max}_{D} V ( D , G ) = {E}_{x \sim {P}_{data} ( x )} [ log D ( x ) ] + {E}_{z \sim {P}_{z} ( z )} [ log ( 1 - D ( G ( z ) ) ) ]$$

where, P_{data}(x) represents a real data distribution, P_{z}(z) represents a noise distribution input by a generator, E represents an expected value.

The generator captures a distribution of real datasets and generates data real to the fullest extent; the discriminator judges whether the data is real or not; in this way, continuous iterative adversarial training simultaneously improves performance of the generator and the discriminator, and reaches its goal, that is, a balanced state in which the generator can produce data that is real enough that the discriminator cannot distinguish between real data and generated data.

Specifically, in S3, building a model for simulating multi-temporal power grid operation trace by means of a Stacking algorithm. By way of analyzing actional changes of power grids at different time points, this model can use historical data to simulate operation trace of power grids at future time points, make it helpful to identify potential risks and optimize decision-making.

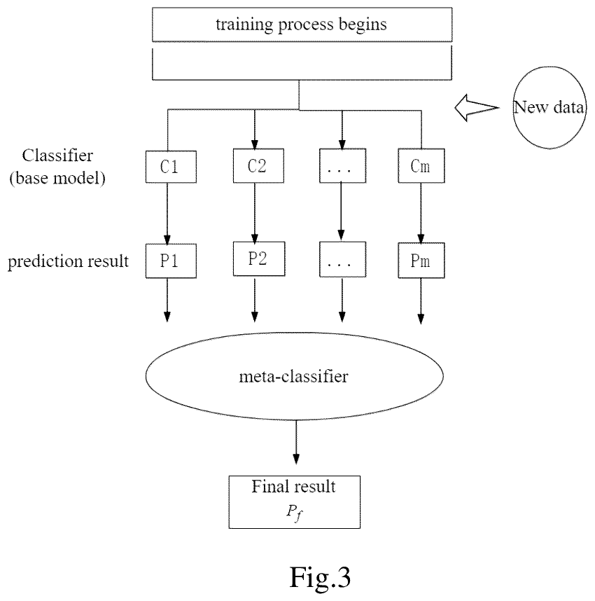

As shown in FIG. 3, Stacking is an integrated learning method used to improve predictive performance of models. It combines prediction results of a plurality of foundation models to achieve better performance. The basic idea of Stacking is to use various learning algorithms to learn an identical dataset and combine their output results to form a stronger, integrated model.

The step of building a model for simulating multi-temporal power grid operation trace by means of a Stacking algorithm is executed by the following sub-steps.
S31 Selecting various machine learning algorithms as a foundation model. For example, linear regression, decision trees, support vector machines, neural networks and the like.
S32 Training all foundation models by using a set of original power grid sample data with performed feature reduction, and enabling each foundation model to learn independently and generate a prediction; and using each foundation model to predict an original training set, so as to obtain a prediction result of each foundation model.
S33 Using a prediction result of each foundation model as a meta-feature, and selecting one foundation model as a meta-model, then training each meta-model with a corresponding meta-feature, so as to obtain a final prediction result.

Specifically, in S4, generating trace data based on the power grid digital twin model, and combining the trace data with real-time data to form a hybrid dataset, which is input into the model for simulating multi-temporal power grid operation trace for analysis and assessment. By way of analyzing the hybrid dataset thoroughly, it is possible to evaluate performance of power grids under various operation conditions, detect anomalies and faults in a timely manner, and provide precise decision support.

The above embodiments are only to illustrate the technical solutions of the present invention and not pose any limitations on it. Although the present invention has been described in detail with reference to the above embodiments, a person skilled in the art can still make modifications or equivalent substitutions to the specific embodiments of the present invention. Any such modifications or equivalent substitutions that do not depart from the essence and scope of the present invention still fall within the protection scope of the pending claims of the present invention.

What is claimed is:

1. A method for analyzing multi-temporal grid operation trace based on digital twins, comprising the steps of
S1 performing feature reduction on a set of original power grid sample data;
S2 based on the set of original power grid sample data with performed feature reduction, building a power grid digital twin model;
S3 based on the set of original power grid sample data with performed feature reduction, building a model for simulating multi-temporal power grid operation trace; and
S4 generating trace data based on the power grid digital twin model, and inputting a hybrid dataset composed of the trace data and real-time data into the model for simulating multi-temporal power grid operation trace for analysis and assessment.

2. The method for analyzing multi-temporal grid operation trace based on digital twins, according to claim 1, wherein in S1, the set of original power grid sample data involves load demand, power generation, line losses and transformer temperature characteristics.

3. The method for analyzing multi-temporal grid operation trace based on digital twins, according to claim 1, wherein S1 further includes the step of performing feature reduction on a set of original power grid sample data by means of a Relief algorithm.

4. The method for analyzing multi-temporal grid operation trace based on digital twins, according to claim 1, wherein S2 further includes the step of building a power grid digital twin model by means of a generative adversarial network, and the power grid digital twin model is configured to simulate operation states of power grids and map characteristics of power grids under different scenarios, so as to provide emulation support for subsequently simulating multi-temporal power grid operation trace.

5. The method for analyzing multi-temporal grid operation trace based on digital twins, according to claim 1, wherein S3 further includes the step of building a model for simulating multi-temporal power grid operation trace by means of a Stacking algorithm.

6. The method for analyzing multi-temporal grid operation trace based on digital twins, according to claim 3, wherein the step of performing feature reduction on a set of original power grid sample data by means of a Relief algorithm is executed by the following sub-steps:
S11 initialization and random instance selection:
selecting a set of original power grid sample data with performed feature reduction (D={(x₁,y₁), (x₂,y₂), . . . , (xₙ,yₙ)} where xᵢ represents a feature vector and yᵢ represents a corresponding class label, then initializing a weight W[j] of each feature as zero, where (j=1, 2, . . . , m) and randomly selecting an instance x from the set of original power grid sample data with performed feature reduction as a current instance;
S12 location of nearest neighbors and calculation of similarity:
computing a nearest neighbor of the current instance x, and calculating similarity in distance metric, wherein for a feature j, calculation of similarity can be defined as:
$$similarity ( {x}_{i} , {x}_{j} ) = exp ( - \frac{{d ( {x}_{i} , {x}_{j} )}^{2}}{{σ}^{2}} )$$
where, (d(xᵢ,xⱼ)) represents a distance between an instance xᵢ and an instance xⱼ, σ represents an adjustment parameter that controls a range of similarity;
S13 update on feature weights
updating a feature weight for each feature J based on located similar and dissimilar neighbors; in other words, increasing a similarity score of a similar neighbor with respect to a current instance feature value, and decreasing a similarity score of a dissimilar neighbor;
$$W [ j ] ← W [ j ] + similarity ( x , {x}_{hit} ) - similarity ( x , {x}_{miss} )$$
where, the similar neighbor (xₕᵢₜ) is the most similar instance among identical classes; the dissimilar neighbor (xₘᵢₛₛ) is the most similar instance among different classes; and
repeating a course from S11-S13 many times until reaching a preset number of iterations or a convergence.

7. The method for analyzing multi-temporal grid operation trace based on digital twins, according to claim 4, wherein the generative adversarial network consists of a generator and a discriminator, and the generator performs a function of producing data real to the fullest extent from random noise, accepting a random noise vector z as input and outputting generated data G(z); and the discriminator performs a function of judging whether input data is real data x or fake data z generated by a generator, and the discriminator outputs D(x) or D(G(z)), indicating a probability of the input data being real;
a process of training a power grid digital twin model is executed by minimizing an adversarial loss between the generator and the discriminator, and such a process is expressed by the following optimization objective function:
$${min}_{G} {max}_{D} V ( D , G ) = {E}_{x \sim {P}_{data} ( x )} [ log D ( x ) ] + {E}_{z \sim {P}_{z} ( z )} [ log ( 1 - D ( G ( z ) ) ) ]$$
where, P_{data}(x) represents a real data distribution, P_{z}(z) represents a noise distribution input by a generator, E represents an expected value;
the generator captures a distribution of real datasets and generates data real to the fullest extent; the discriminator judges whether the data is real or not; in this way, continuous iterative adversarial training simultaneously improves performance of the generator and the discriminator, and reaches a goal, that is, a balanced state in which the generator can produce data that is real enough that the discriminator cannot distinguish between real data and generated data.

8. The method for analyzing multi-temporal grid operation trace based on digital twins, according to claim 5, wherein the step of building a model for simulating multi-temporal power grid operation trace by means of a Stacking algorithm is executed by the following sub-steps:
S31 selecting various machine learning algorithms as a foundation model;
S32 training all foundation models by using a set of original power grid sample data with performed feature reduction, and enabling each foundation model to learn independently and generate a prediction; and using each foundation model to predict an original training set, so as to obtain a prediction result of each foundation model; and
S33 using a prediction result of each foundation model as a meta-feature, and selecting one foundation model as a meta-model, then training each meta-model with a corresponding meta-feature, so as to obtain a final prediction result.
